(19) United States
(12) Patent Application Publication
(10) Pub. No.: US 2025/0291106 A1
(43) Pub. Date: Sep. 18, 2025

(54) OPTICAL DEVICE, RECEIVER DEVICE, TRANSCEIVER DEVICE, COMMUNICATION SYSTEM, TERMINAL DEVICE, AND OPTICAL SYSTEM

(71) Applicant: TDK CORPORATION, Tokyo (JP)

(72) Inventors: Tetsuya SHIBATA, Tokyo (JP); Tomohito Mizuno, Tokyo (JP); Hideaki Fukuzawa, Tokyo (JP)

(73) Assignee: TDK CORPORATION, Tokyo (JP)

(21) Appl. No.: 19/077,778

(22) Filed: Mar. 12, 2025

(30) Foreign Application Priority Data
Mar. 13, 2024 (JP) 2024-038554

(51) Int. Cl. G02B 6/02; G02B 6/42

(52) U.S. Cl. CPC G02B 6/02057; G02B 6/4246

(57) ABSTRACT

An optical device which is packaged, a receiver device, a transceiver device, a communication system, a terminal device, and an optical system are provided. The optical device includes a waveguide and a magnetic element. The waveguide includes a core in which light propagates and a clad which covers the core. The core includes a diffraction grating on a first surface. The magnetic element is located above the first surface in the clad. The magnetic element includes a first ferromagnetic layer, a second ferromagnetic layer, and a spacer layer which is located between the first ferromagnetic layer and the second ferromagnetic layer.

### BACKGROUND OF THE INVENTION

### Field of the Invention

The present invention relates to an optical device, a receiver device, a transceiver device, a communication system, a terminal device, and an optical system.

### Description of Related Art

Photoelectric converters have been used for various purposes.

For example, Patent Document 1 discloses a receiver device that receives an optical signal using a photodiode. A photodiode is, for example, a pn junction diode using a pn junction of semiconductor and converts light to an electrical signal.

For example, Patent Document 2 discloses a novel optical device using a magnetic element. A magnetic state of a magnetic element changes and a resistance value thereof changes when the magnetic element is irradiated with light.

### [Patent Documents]

[Patent Document 1] Japanese Unexamined Patent Application, First Publication No. 2001-292107
[Patent Document 2] Japanese Unexamined Patent Application, First Publication No. 2023-47553

### SUMMARY OF THE INVENTION

For example, as described in Patent Document 2, when it is intended to emit laser light from a waveguide to a space and to detect the laser light using a magnetic element, light use efficiency decreases due to reflection based on a refractive index difference between the waveguide and the space. When a waveguide and a magnetic element are manufactured as separate components, adjustment of an optical axis or the like is needed.

The present invention was made in consideration of the aforementioned circumstances, and an objective thereof is to provide an optical device which is packaged, a receiver device, a transceiver device, a communication system, a terminal device, and an optical system.

In order to achieve the aforementioned object, the following means are provided.

An optical device according to an embodiment includes a waveguide and at least one magnetic element. The waveguide includes a core in which light propagates and a clad which covers the core. The core includes a diffraction grating on a first surface. The at least one magnetic element is located above the first surface in the clad. The at least one magnetic element includes a first ferromagnetic layer, a second ferromagnetic layer, and a spacer layer which is located between the first ferromagnetic layer and the second ferromagnetic layer.

The optical device according to the aspect is packaged.

### BRIEF DESCRIPTION OF THE DRAWINGS

FIG. 1 is a perspective view of an optical device according to a first embodiment.

FIG. 2 is a sectional view of the optical device according to the first embodiment.

FIG. 3 is another sectional view of the optical device according to the first embodiment.

FIG. 4 is an enlarged sectional view of a diffraction grating according to the first embodiment.

FIG. 5 is a sectional view of the vicinity of a magnetic element of the optical device according to the first embodiment.

FIG. 6 is a diagram illustrating an operation example of the magnetic element according to the first embodiment.

FIG. 7 is a diagram illustrating an operation example of the magnetic element according to the first embodiment.

FIG. 8 is a sectional view of an optical device according to a first modified example.

FIG. 9 is a perspective view of an optical device according to a second modified example.

FIG. 10 is a sectional view illustrating a first example of a connection state of a magnetic element in the optical device according to the second modified example.

FIG. 11 is a sectional view illustrating a second example of the connection state of the magnetic element in the optical device according to the second modified example.

FIG. 12 is a diagram schematically illustrating an optical unit according to a first application example.

FIG. 13 is a conceptual diagram of an optical system using the optical unit according to the first application example.

FIG. 14 is a diagram schematically illustrating a transceiver device according to a second application example.

FIG. 15 is a conceptual diagram illustrating an example of a communication system.

FIG. 16 is a conceptual diagram illustrating another example of the communication system.

### DETAILED DESCRIPTION OF THE INVENTION

Hereinafter, an embodiment will be described in detail with appropriate reference to the accompanying drawings. In the drawings used in the following description, featured parts may be conveniently enlarged for the purpose of easy understanding of features, and dimensions, ratios, and the like of constituents may be different from actual ones. Materials, dimensions, and the like exemplified in the following description are merely examples, and the present invention is not limited thereto and can be appropriately modified within ranges in which the advantageous effects of the present invention can be achieved.

Directions are defined. One in-plane direction of a plane in which a substrate extends is defined as an X direction, and a direction perpendicular to the X direction in the plane is defined as a Y direction. For example, a direction in which a core extends in the vicinity of a magnetic element is defined as the X direction. A direction perpendicular to the substrate is defined as a Z direction. The Z direction is an example of a stacking direction of the magnetic element 20. In the following description, the +Z direction may be referred to as “upward,” and the −Z direction may be referred to as “downward.” The +Z direction is a direction directed from a core to a magnetic element. Upward and downward do not necessarily match a direction in which a gravitational force is applied.

### First Embodiment

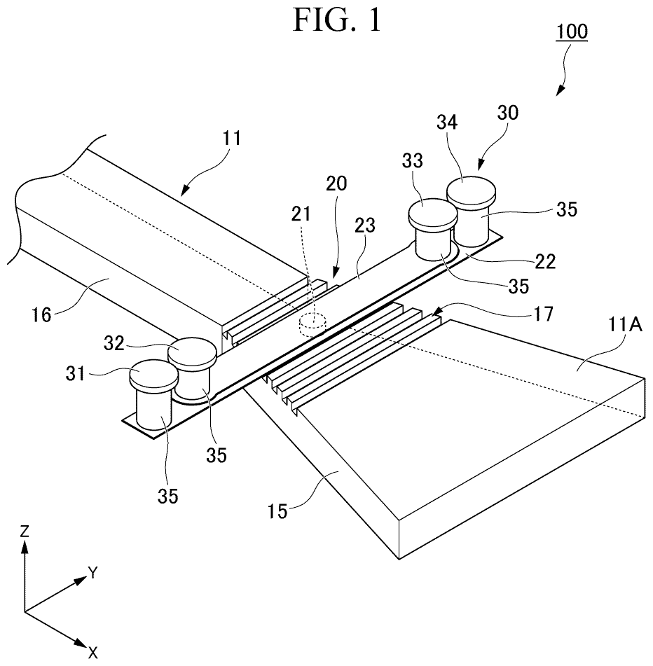

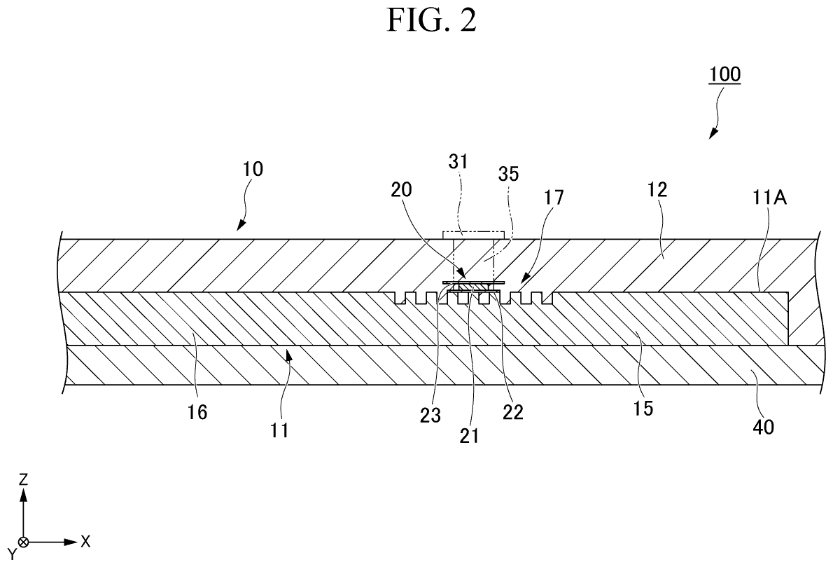

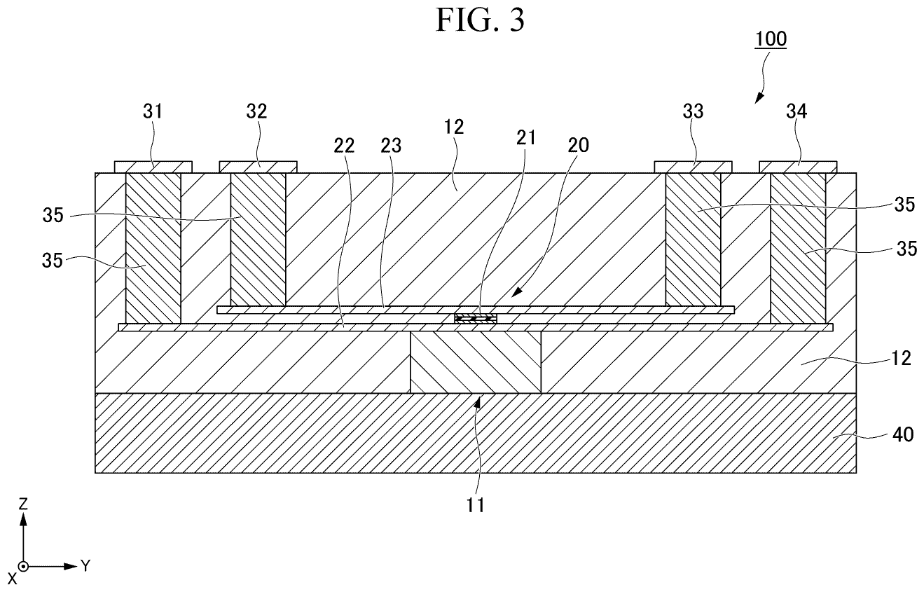

FIG. 1 is a perspective view of an optical device 100 according to a first embodiment. FIGS. 2 and 3 are sectional views of the optical device 100 according to the first embodiment. FIG. 2 illustrates an XZ section passing through the center in the Y direction of a core 11, and FIG. 3 is a YZ section passing through the center of a magnetic element 20. In FIG. 1, a clad 12 and a substrate 40 are not illustrated.

The optical device 100 includes, for example, a waveguide 10, a magnetic element 20, a terminal unit 30, and a substrate 40.

The waveguide 10, the magnetic element 20, and the terminal unit 30 are formed on the substrate 40. The substrate 40 is, for example, a semiconductor substrate, an aluminum oxide substrate, or a sapphire substrate.

The waveguide 10 is a structure forming a path in which light propagates. Light in this specification is not limited to visible light and includes infrared light of longer wavelengths than the visible light and ultraviolet light of shorter wavelengths than the visible light. The wavelength of the visible light is, for example, equal to or greater than 380 nm and less than 800 nm. The wavelength of the infrared light is, for example, equal to or greater than 800 nm and less than 1 mm. The wavelength of the ultraviolet light is, for example, equal to or greater than 200 nm and less than 380 nm. A first end of the waveguide 10 is connected to, for example, an output end of a laser diode. Light propagating in the waveguide 10 is, for example, laser light.

The waveguide 10 includes, for example, a core 11 and a clad 12. The waveguide 10 fully reflects light due to a refractive index difference between the core 11 and the clad 12. Light propagates in the core 11. The clad 12 covers the core 11.

The core 11 includes, for example, lithium niobate as a main component. Some elements of lithium niobate may be replaced with other elements. The clad 12 is formed of, for example, SiO₂, Al₂O₃, MgF₂, La₂O₃, ZnO, HfO₂, MgO, Y₂O₃, CaF₂, or In₂O₃ or a mixture thereof. The material of the core 11 and the material of the clad 12 are not limited to these examples. For example, the core 11 may be formed of a material in which germanium oxide is added to silicon or silicon oxide, and the clad 12 may be formed of silicon oxide. For example, the core 11 may be formed of tantalum oxide (Ta₂O₅), and the clad 12 may be formed of silicon oxide or aluminum oxide.

The core 11 includes, for example, an element installation portion 15 and a light propagating portion 16. The element installation portion 15 is located in front of the light propagating portion 16 in a propagating direction in which light propagates in the core 11. Light reaches the element installation portion 15 via the light propagating portion 16. The element installation portion 15 is a portion in which a magnetic element 20 is installed. A width in the Y direction of the element installation portion 15 may be larger than a width in the Y direction of the light propagating portion 16. Light is applied to the magnetic element 20 in the element installation portion 15. When light spreads in the element installation portion 15, an amount of leakage light from the diffraction grating 17 increases, and light can be easily applied to the magnetic element 20.

The core 11 includes a diffraction grating 17. The diffraction grating 17 is formed on a first surface 11A of the core 11. The diffraction grating 17 is formed in, for example, the element installation portion 15.

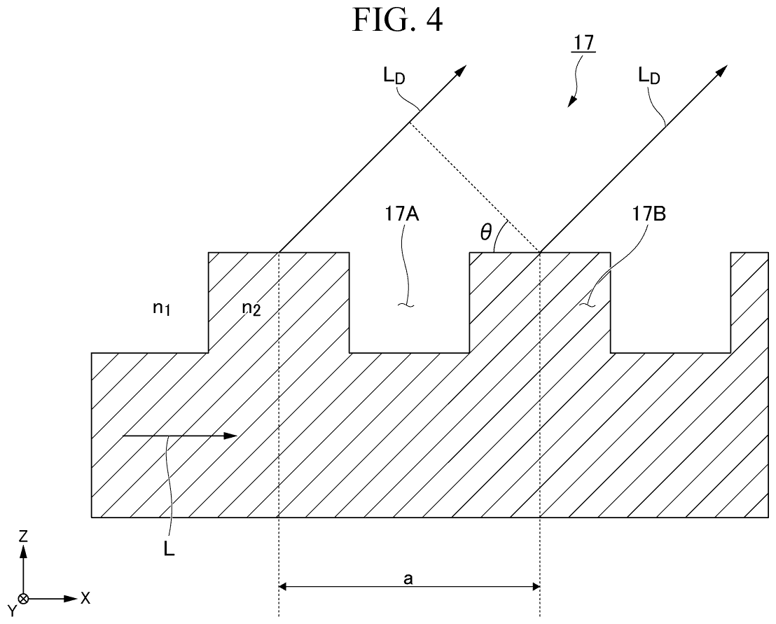

FIG. 4 is an enlarged sectional view of the diffraction grating 17 according to the first embodiment. The diffraction grating 17 includes a plurality of grooves 17A and a plurality of protrusions 17B. The plurality of grooves 17A and the plurality of protrusions 17B cross a propagating direction (for example, the X direction) of light L which propagates in the element installation portion 15. The plurality of grooves 17A and the plurality of protrusions 17B extend, for example, in the Y direction.

The diffraction grating 17 diffracts light L which propagates in the core 11 on the basis of following Basic Expression (1) for a grating coupler. Light L_{D} diffracted by the diffraction grating 17 has a component in the Z direction and is output upward from the core 11.

sin(θ)=(n_{eff}−mλ/a)/n₁ . . . (1)

Here, θ denotes an angle formed by a normal direction of light L_{D} and the XY plane as illustrated in FIG. 4. n_{eff} denotes an effective refractive index and is calculated by n₁×V_{17A}+n₂×V_{17B}. V_{17A} is a volume proportion of the grooves 17A in the diffraction grating 17, and V_{17B} is a volume proportion of the protrusions 17B in the diffraction grating 17. n₁ denotes a refractive index of a material with which the grooves 17A are filled and is a refractive index of the clad 12. n₂ denotes a refractive index of the protrusions 17B and a refractive index of the core 11. m is the number of degrees. λ denotes a wavelength of light L propagating in the core 11. a denotes a pitch length between the protrusions 17B.

The effective refractive index n_{eff} of the diffraction grating 17 is preferably larger than a value obtained by dividing the wavelength λ of light L by the pitch length a between the protrusions 17B. When the diffraction grating 17 satisfies these conditions, light L can be appropriately output upward from the core 11.

The magnetic element 20 is provided in the clad 12. The magnetic element 20 is located in a layer other than the core 11 and above the core 11 in the Z direction. The magnetic element 20 is located above the first surface 11A of the core 11. The magnetic element 20 is located, for example, at the same position as the diffraction grating 17 or in front of the diffraction grating 17 in the propagating direction (for example, the X direction) of light L propagating in the core 11. In the example illustrated in FIG. 2, the magnetic element 20 is located at the same position as the diffraction grating 17 in the X direction. When seen in the Z direction, the magnetic element 20 is located at a position overlapping the diffraction grating 17. For example, the magnetic element 20 is located in contact with the diffraction grating 17 and is located on the diffraction grating 17.

The magnetic element 20 converts a state or a change in state of the applied light to an electrical signal. The magnetic element 20 is irradiated, for example, with light of a wavelength equal to or greater than 400 nm and equal to or less than 1500 nm.

The magnetic element 20 generates a voltage when it is irradiated with light. When the state of light applied thereto changes, a resistance value in the Z direction of the magnetic element 20 changes with the change in the state of light. When the state of light applied to the magnetic element 20 changes, an output voltage from the magnetic element 20 changes with the change in the state of light.

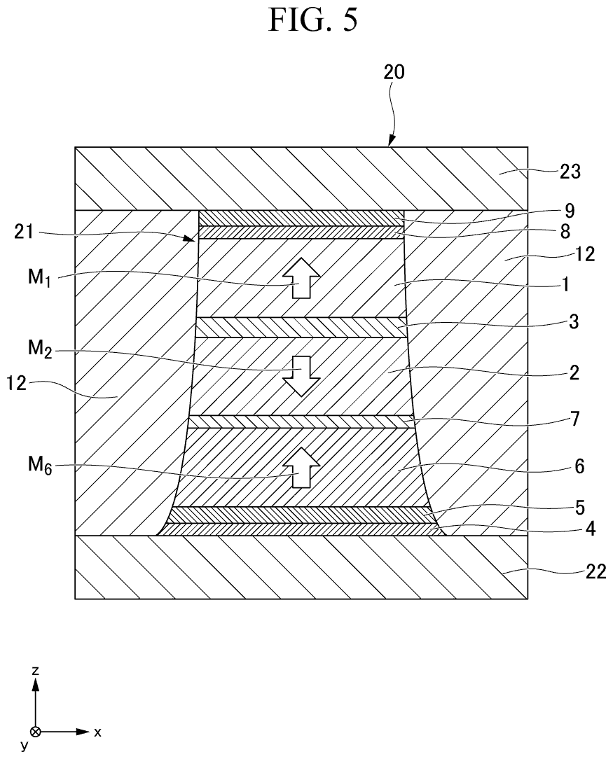

FIG. 5 is a sectional view of the vicinity of a magnetic element 20 of the optical device 100 according to the first embodiment. The magnetic element 20 includes a laminate 21, a first electrode 22, and a second electrode 23.

The first electrode 22 is located on the substrate 40 side of the laminate 21. The first electrode 22 has conductivity. The first electrode 22 is formed of, for example, a metal such as Cu, Al, or Au. Ta or Ti may be stacked on or under the metal. The first electrode 22 may be formed of a stacked film of Cu and Ta, a stacked film of Ta, Cu, and Ti, or a stacked film of Ta, Cu, and TaN. The first electrode 22 may be formed of TiN or TaN.

The first electrode 22 may be formed of, for example, a metal including at least one element selected from a group constituting of ruthenium, molybdenum, and tungsten. The first electrode 22 may be a single-layered film of one of ruthenium, molybdenum, and tungsten or may be a stacked film including a layer of at least one of ruthenium, molybdenum, and tungsten. Ruthenium, molybdenum, and tungsten have high melting points (equal to or higher than 2000° C.) and high thermal resistance. The first electrode 22 including these elements is not likely to deteriorate even when heat treatment for crystalizing the laminate 21 and heat treatment in the semiconductor process are performed thereon.

The first electrode 22 may be a transparent electrode having transmissivity to light in a use wavelength band. For example, it is preferable that the first electrode 22 transmits 80% or more of light in the use wavelength band. The first electrode 22 is formed of, for example, oxides such as indium tin oxide (ITO), indium zinc oxide (IZO), zinc oxide (ZnO), or indium gallium zinc oxide (IGZO). The first electrode 22 may be a metal film with a thickness of about 3 nm to 10 nm. When the first electrode 22 is a transparent electrode, light L_{D} can be applied to the laminate 21 from below, and it is possible to efficiently irradiate the laminate 21 with light.

The second electrode 23 is opposite to the first electrode 22. The first electrode 22 and the second electrode 23 interpose the laminate 21 in the Z direction. The second electrode 23 is formed of a conductive material. The second electrode 23 is formed of, for example, metal such as Cu, Al, or Au. In the second electrode 23, Ta or Ti may be stacked on or under the metal. A stacked film of Cu and Ta, a stacked film of Ta, Cu, and Ti, or a stacked film of Ta, Cu, and TaN may be used as the second electrode 23. TiN or TaN may be used as the second electrode 23.

The laminate 21 is interposed between the first electrode 22 and the second electrode 23. The laminate 21 includes, for example, a first ferromagnetic layer 1, a second ferromagnetic layer 2, and a spacer layer 3. The spacer layer 3 is located between the first ferromagnetic layer 1 and the second ferromagnetic layer 2. The laminate 21 may include other layers. The laminate 21 may include, for example, a buffer layer 4, a seed layer 5, a third ferromagnetic layer 6, a magnetic coupling layer 7, a perpendicular magnetization inducing layer 8, and a cap layer 9.

The magnetic element 20 is a magnetic element including a ferromagnetic substance. For example, when the spacer layer 3 is formed of an insulator, the magnetic element 20 includes a magnetic tunnel junction (MTJ) which is constituted by the first ferromagnetic layer 1, the spacer layer 3, and the second ferromagnetic layer 2. This element is referred to as an MTJ element. In this case, the magnetic element 20 can exhibit a tunnel magnetoresistance (TMR) effect. When the spacer layer 3 is formed of a metal, the magnetic element 20 can exhibit a giant magnetoresistance (GMR) effect. This element is referred to as a GMR element. The magnetic element 20 is referred to as different names such as an MTJ element and a GMR element according to the material of the spacer layer 3 and is also collectively referred to as a magnetoresistance effect element. A resistance value in the Z direction (a resistance value when a current flows in the Z direction) of the magnetic element 20 changes according to a relative change of a magnetization state of the first ferromagnetic layer 1 and a magnetization state of the second ferromagnetic layer 2.

The first ferromagnetic layer 1 is a light sensing layer in which a magnetization state changes when light is externally applied thereto. The first ferromagnetic layer 1 is also referred to as a magnetization free layer. The magnetization free layer is a layer including a magnetic substance in which a magnetization state changes when predetermined energy is externally applied thereto. The predetermined energy from the outside includes, for example, light which is applied from the outside, a current which flows in the Z direction of the magnetic element 20, and an external magnetic field. The magnetization state of the first ferromagnetic layer 1 changes according to an intensity of light applied to the first ferromagnetic layer 1 (light applied to the magnetic element 20).

The first ferromagnetic layer 1 includes a ferromagnetic substance. The first ferromagnetic layer 1 includes, for example, at least one of magnetic elements such as Co, Fe, and Ni. The first ferromagnetic layer 1 may include elements such as B, Mg, Hf, and Gd in addition to the aforementioned magnetic elements. The first ferromagnetic layer 1 may be formed of, for example, an alloy including a magnetic element and a nonmagnetic element. The first ferromagnetic layer 1 may include a plurality of layers. The first ferromagnetic layer 1 is, for example, a CoFeB alloy layer, a laminate in which a CoFeB alloy layer is interposed between Fe layers, or a laminate in which a CoFeB alloy layer is interposed between CoFe layers. In general, “ferromagnetism” includes “ferrimagnetism.” The first ferromagnetic layer 1 may exhibit ferrimagnetism. On the other hand, the first ferromagnetic layer 1 may exhibit ferromagnetism other than ferrimagnetism. For example, the CoFeB alloy exhibits ferromagnetism other than ferrimagnetism.

The first ferromagnetic layer 1 may be an in-plane magnetized film having an easy magnetization axis in an in-plane direction (some directions in the xy plane) or may be a perpendicularly magnetized film including an easy magnetization axis in a plane-perpendicular direction (the Z direction).

The thickness of the first ferromagnetic layer 1 is, for example, equal to or greater than 1 nm and equal to or less than 5 nm. For example, it is preferable that the thickness of the first ferromagnetic layer 1 be equal to or greater than 1 nm and equal to or less than 2 nm. When the first ferromagnetic layer 1 is a perpendicularly magnetized film and the thickness of the first ferromagnetic layer 1 is small, a perpendicular magnetic anisotropy application effect from layers located on and below the first ferromagnetic layer 1 is strengthened, and the perpendicular magnetic anisotropy of the first ferromagnetic layer 1 is enhanced. That is, when the perpendicular magnetic anisotropy of the first ferromagnetic layer 1 is high, a force for returning magnetization M₁ in the Z direction is increased. On the other hand, when the thickness of the first ferromagnetic layer 1 is large, the perpendicular magnetic anisotropy application effect from layers located on and below the first ferromagnetic layer 1 is relatively weakened, and the perpendicular magnetic anisotropy of the first ferromagnetic layer 1 is weakened.

When the thickness of the first ferromagnetic layer 1 decreases, a volume serving as a ferromagnetic substance decreases. When the thickness of the first ferromagnetic layer 1 increases, the volume serving as a ferromagnetic substance increases. Magnetization reactivity of the first ferromagnetic layer 1 when external energy is applied thereto is inversely proportional to a product (KuV) of the magnetic anisotropy (Ku) and the volume (V) of the first ferromagnetic layer 1. That is, when the product of the magnetic anisotropy and the volume of the first ferromagnetic layer 1 decreases, the reactivity to light increases. From this viewpoint, it is preferable to appropriately design the magnetic anisotropy of the first ferromagnetic layer 1 and to decrease the volume of the first ferromagnetic layer 1 in order to increase the reactivity to light.

When the thickness of the first ferromagnetic layer 1 is larger than 2 nm, for example, an insertion layer formed of Mo or W may be provided in the first ferromagnetic layer 1. That is, a laminate in which a ferromagnetic layer, an insertion layer, and a ferromagnetic layer are sequentially stacked in the Z direction may be used as the first ferromagnetic layer 1. The perpendicular magnetic anisotropy of the first ferromagnetic layer 1 as a whole is increased by interface magnetic anisotropy at an interface between the insertion layer and the ferromagnetic layer. The thickness of the insertion layer ranges, for example, from 0.1 nm to 1.0 nm.

The second ferromagnetic layer 2 is a magnetization fixed layer. The magnetization fixed layer is a layer formed of a magnetic substance in which a state of magnetization M₂ is less likely to change than the magnetization free layer when predetermined energy is externally applied thereto. For example, a magnetization direction of the magnetization fixed layer is less likely to change than that of the magnetization free layer when predetermined energy is externally applied thereto. For example, a magnetization magnitude of the magnetization fixed layer is less likely to change than that of the magnetization free layer when predetermined energy is externally applied thereto. For example, a coercive force of the second ferromagnetic layer 2 is larger than a coercive force of the first ferromagnetic layer 1. The second ferromagnetic layer 2 includes, for example, an easy magnetization axis of the same direction as the first ferromagnetic layer 1. The second ferromagnetic layer 2 may be an in-plane magnetized film or a perpendicularly magnetized film.

For example, the material of the second ferromagnetic layer 2 is the same as the first ferromagnetic layer 1. The second ferromagnetic layer 2 may be, for example, a multi-layered layer in which Co with a thickness of 0.4 nm to 1.0 nm and Pt with a thickness of 0.4 nm to 1.0 nm are alternately stacked by several turns. The second ferromagnetic layer 2 may be, for example, a laminate in which Co with a thickness of 0.4 nm to 1.0 nm, Mo with a thickness of 0.1 nm to 0.5 nm, a CoFeB alloy with a thickness of 0.3 nm to 1.0 nm, and Fe with a thickness of 0.3 nm to 1.0 nm are alternately stacked.

For example, the magnetization M₂ of the second ferromagnetic layer 2 may be magnetically coupled to magnetization M₆ of the third ferromagnetic layer 6 with the magnetic coupling layer 7 interposed therebetween. In this case, the second ferromagnetic layer 2, the magnetic coupling layer 7, and the third ferromagnetic layer 6 may be collectively referred to as a magnetization fixed layer. Details of the magnetic coupling layer 7 and the third ferromagnetic layer 6 will be described later.

In FIG. 5, a bottom-pin structure in which the second ferromagnetic layer 2 which is a magnetization fixed layer is closer to the substrate 40 than the first ferromagnetic layer 1 is illustrated, but a top-pin structure in which the second ferromagnetic layer 2 which is a magnetization fixed layer is more apart from the substrate 40 than the first ferromagnetic layer 1 may be employed.

The spacer layer 3 is a layer which is disposed between the first ferromagnetic layer 1 and the second ferromagnetic layer 2. The spacer layer 3 is constituted by a layer formed of a conductor, an insulator, or a semiconductor or a layer including a conductive spot formed of a conductor in an insulator. The spacer layer 3 is, for example, a nonmagnetic layer. The thickness of the spacer layer 3 can be adjusted according to alignment directions of the magnetization of the first ferromagnetic layer 1 and the magnetization of the second ferromagnetic layer 2 in an initial state which will be described later.

When the spacer layer 3 is formed of an insulating material, a material including aluminum oxide, magnesium oxide, titanium oxide, or silicon oxide can be used as the material of the spacer layer 3. This insulating material may include an element such as Al, B, Si, or Mg or a magnetic element such as Co, Fe, or Ni. By adjusting the thickness of the spacer layer 3 such that a high TME effect is exhibited between the first ferromagnetic layer 1 and the second ferromagnetic layer 2, a high magnetoresistance change rate is obtained. In order to efficiently use the TMR effect, the thickness of the spacer layer 3 may be set to about 0.5 nm to 5.0 nm or about 1.0 nm to 2.5 nm.

When the spacer layer 3 is formed of a nonmagnetic conductive material, a conductive material such as Cu, Ag, Au, or Ru can be used. In order to efficiently use the GMR effect, the thickness of the spacer layer 3 may be set to about 0.5 nm to 5.0 nm or about 2.0 nm to 3.0 nm.

When the spacer layer 3 is formed of a nonmagnetic semiconductor material, a material such as zinc oxide, indium oxide, tin oxide, germanium oxide, gallium oxide, or ITO can be used. In this case, the thickness of the spacer layer 3 may be set to about 1.0 nm to 4.0 nm.

When a layer including a conductive spot formed of a conductor in a nonmagnetic insulator is used as the spacer layer 3, a structure in which a conductive spot formed of a nonmagnetic conductor such as Cu, Au, or Al is included in a nonmagnetic insulator formed of aluminum oxide or magnesium oxide may be employed. The conductor may include a magnetic element such as Co, Fe, or Ni. In this case, the thickness of the spacer layer 3 may be set to about 1.0 nm to 2.5 nm. The conductive spot is, for example, a columnar member with a diameter of 1 nm to 5 nm when seen in a direction perpendicular to a film plane.

The third ferromagnetic layer 6 is magnetically coupled to, for example, the second ferromagnetic layer 2. Magnetic coupling is, for example, antiferromagnetic coupling and is caused by an RKKY interaction. The material of the third ferromagnetic layer 6 is, for example, the same as the first ferromagnetic layer 1.

The magnetic coupling layer 7 is located between the second ferromagnetic layer 2 and the third ferromagnetic layer 6. The magnetic coupling layer 7 is formed of, for example, Ru or Ir.

The buffer layer 4 is a layer for buffering lattice mismatch between different crystals. The buffer layer 4 is, for example, a metal including at least one type of element selected from a group consisting of Ta, Ti, Zr, and Cr or a nitride including at least one type of element selected from a group consisting of Ta, Ti, Zr, and Cu. More specifically, the buffer layer 4 is formed of, for example, Ta (simple substance), an NiCr alloy, tantalum nitride (TaN), or copper nitride (CuN). The thickness of the buffer layer 4 is, for example, equal to or greater than 1 nm and equal to or less than 5 nm. The buffer layer 4 is, for example, amorphous. For example, the buffer layer 4 is located between the seed layer 5 and the second electrode 23 and is in contact with the second electrode 23. The buffer layer 4 curbs an influence of a crystal structure of the second electrode 23 on a crystal structure of the magnetic element 20.

The seed layer 5 increases crystallizability of a layer which is stacked on the seed layer 5. For example, the seed layer 5 is located between the buffer layer 4 and the third ferromagnetic layer 6 and is located on the buffer layer 4. The seed layer 5 is formed of, for example, Pt, Ru, Zr, or NiFeCr. The thickness of the seed layer 5 is, for example, equal to or greater than 1 nm and equal to or less than 5 nm.

The cap layer 9 is located between the first ferromagnetic layer 1 and the second electrode 23. The cap layer 9 may include a perpendicular magnetization inducing layer 8 which is stacked on the first ferromagnetic layer 1 and which is in contact with the first ferromagnetic layer 1. The cap layer 9 prevents damage on an underlying layer in the course of processing and enhances crystallizability of an underlying layer at the time of annealing.

The perpendicular magnetization inducing layer 8 induces perpendicular magnetic anisotropy of the first ferromagnetic layer 1. The perpendicular magnetization inducing layer 8 is formed of, for example, magnesium oxide, W, Ta, or Mo. When the perpendicular magnetization inducing layer 8 is formed of magnesium oxide, it is preferable that magnesium oxide be deficient in oxygen in order to enhance conductivity. The thickness of the perpendicular magnetization inducing layer 8 is, for example, equal to or greater than 0.5 nm and equal to or less than 5.0 nm.

The terminal unit 30 includes, for example, a first terminal 31, a second terminal 32, a third terminal 33, a fourth terminal 34, and a plurality of via-lines 35. The first terminal 31, the second terminal 32, the third terminal 33, and the fourth terminal 34 are formed on the clad 12. The first terminal 31 and the fourth terminal 34 are electrically connected to the first electrode 22 via the via-line 35. The second terminal 32 and the third terminal 33 are electrically connected to the second electrode 23 via the via-line 35. A current or a voltage is input to the first terminal 31, and the second terminal 32 is connected to a reference potential. A signal is output from the third terminal 33, and the fourth terminal 34 is connected to the reference potential. The first terminal 31, the second terminal 32, the third terminal 33, the fourth terminal 34, and the plurality of via-lines 35 include a conductive material.

Operations of the optical device 100 will be described below. An output voltage from the optical device 100 changes with a change in intensity of light applied to the magnetic element 20. The output voltage from the optical device 100 changes with a change in resistance value in the Z direction of the magnetic element 20.

The magnetic element 20 is irradiated with light L which propagates in the waveguide 10. The light L propagates in the X direction in the waveguide 10, is diffracted to the Z direction by the diffraction grating 17, and is applied to the magnetic element 20.

For example, when the intensity of light applied to the magnetic element 20 changes from a first intensity to a second intensity, a resistance value in the Z direction of the magnetic element 20 changes. The first intensity may be an intensity when the intensity of light applied to the magnetic element 20 is zero. When the resistance value in the Z direction of the magnetic element 20 changes, the output voltage from the magnetic element 20 changes.

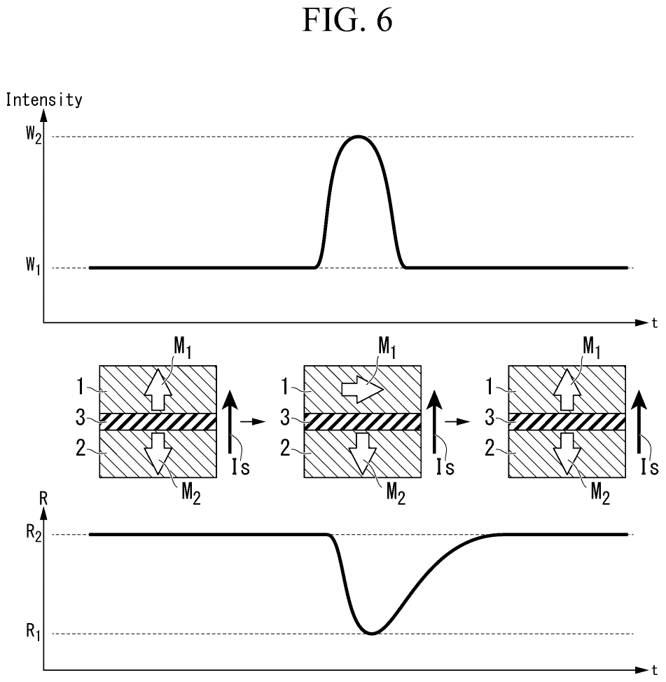

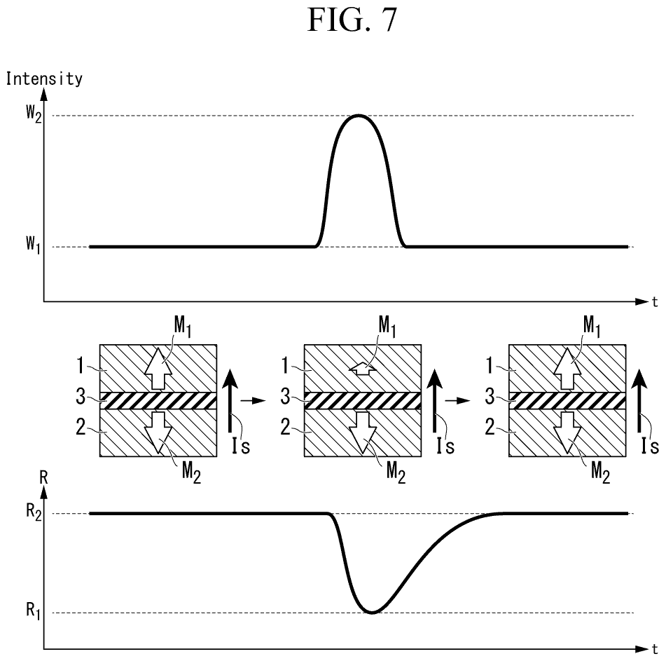

FIGS. 6 and 7 are diagrams illustrating an example of the operation of the magnetic element 20 according to the first embodiment. FIG. 6 is a diagram illustrating a first mechanism of the operation example, and FIG. 7 is a diagram illustrating a second mechanism of the operation example. In the upper graphs of FIGS. 6 and 7, the vertical axis represents an intensity of light applied to the first ferromagnetic layer 1, and the horizontal axis represents time. In the lower graphs of FIGS. 6 and 7, the vertical axis represents a resistance value in the Z direction of the magnetic element 20, and the horizontal axis represents time.

First, in a state (hereinafter referred to as an initial state) in which light with a first intensity W₁ is applied to the first ferromagnetic layer 1, the magnetization M₁ of the first ferromagnetic layer 1 and the magnetization M₂ of the second ferromagnetic layer 2 are anti-parallel to each other, and the resistance value in the Z direction of the magnetic element 20 indicates a second resistance value R₂. Here, a state in which the intensity of light applied to the first ferromagnetic layer 1 is zero may be defined as a state in which light with the first intensity W₁ is applied.

By allowing a sensing current Is to flow in the Z direction of the magnetic element 20, a voltage is generated across terminals in the Z direction of the magnetic element 20. The output voltage from the magnetic element 20 is generated between the first electrode 22 and the second electrode 23.

In the example illustrated in FIG. 6, it is preferable that the sensing current Is flow from the second ferromagnetic layer 2 to the first ferromagnetic layer 1. By allowing the sensing current Is to flow in this direction, a spin transfer torque in a direction opposite to the magnetization M₂ of the second ferromagnetic layer 2 acts on the magnetization M₁ of the first ferromagnetic layer 1, and the magnetization M₁ and the magnetization M₂ in the initial state are likely to be antiparallel to each other.

Subsequently, the intensity of light applied to the first ferromagnetic layer 1 changes from the first intensity W₁ to the second intensity W₂. For example, when a light pulse is applied to the magnetic element 20, the intensity of light applied to the first ferromagnetic layer 1 changes from the first intensity W₁ to the second intensity W₂. Light with the second intensity W₂ has a larger intensity than light with the first intensity W₁.

The second intensity W₂ is larger than the first intensity W₁, and the magnetization M₁ of the first ferromagnetic layer 1 changes from the initial state. The state of the magnetization M₁ of the first ferromagnetic layer 1 in a state in which light is not applied to the first ferromagnetic layer 1 and the state of the magnetization M₁ of the first ferromagnetic layer 1 in a state in which light with the second intensity W₂ is applied thereto are different from each other. The state of the magnetization M₁ includes, for example, a tilt angle with respect to the Z direction and a magnitude.

For example, when the intensity of light applied to the first ferromagnetic layer 1 changes from the first intensity W₁ to the second intensity W₂ as illustrated in FIG. 6, the magnetization M₁ is tilted with respect to the Z direction. For example, when the intensity of light applied to the first ferromagnetic layer 1 changes from the first intensity W₁ to the second intensity W₂ as illustrated in FIG. 7, the magnitude of the magnetization M₁ decreases. For example, when the magnetization M₁ of the first ferromagnetic layer 1 is tilted with respect to the Z direction according to the intensity of the applied light, the tilt angle is, for example, greater than 0° and less than 90°.

When the magnetization M₁ of the first ferromagnetic layer 1 changes from the initial state with application of a light pulse to the magnetic element 20, the resistance value in the Z direction of the magnetic element 20 indicates the first resistance value R₁, and the output voltage from the magnetic element 20 changes from a first value to a second value. As a result, the output from the optical device 100 changes. The first resistance value R₁ is less than the second resistance value R₂. The second value is less than the first value. The first resistance value R₁ is a value between a resistance value (the second resistance value R₂) when the magnetization M₁ and the magnetization M₂ are antiparallel and a resistance value when the magnetization M₁ and the magnetization M₂ are parallel.

In the example illustrated in FIG. 6, a spin transfer torque in a direction which is opposite to the magnetization M₂ of the second ferromagnetic layer 2 acts on the magnetization M₁ of the first ferromagnetic layer 1. Accordingly, the magnetization M₁ is going to return to the state in which it is antiparallel to the magnetization M₂, and the magnetization M₁ returns to state in which it is antiparallel to the magnetization M₂ when the intensity of light applied to the first ferromagnetic layer 1 changes from the second intensity to the first intensity. In the example illustrated in FIG. 7, when the intensity of light applied to the first ferromagnetic layer 1 returns to the first intensity W₁, the magnitude of the magnetization M₁ of the first ferromagnetic layer 1 returns to the original magnitude, and the magnetic element 20 returns to the initial state. In any case, the resistance value in the Z direction of the magnetic element 20 returns to the second resistance value R₂. That is, when the intensity of light applied to the first ferromagnetic layer 1 changes from the second intensity W₂ to the first intensity W₁, the resistance value in the Z direction of the magnetic element 20 changes from the first resistance value R₁ to the second resistance value R₂.

The output voltage from the optical device 100 changes with a change of the intensity of light applied to the magnetic element 20, and the change of the intensity of the applied light can be converted to a change of the output voltage from the magnetic element 20. That is, the optical device 100 can convert light to an electrical signal. For example, a signal when the output voltage from the optical device 100 is equal to or greater than a threshold value is defined as a first signal (for example, “1”), and a signal when the output voltage is less than the threshold value is defined as a second signal (for example, “0”).

An example in which the magnetization M₁ and the magnetization M₂ in the initial state are antiparallel has been described above, but the magnetization M₁ and the magnetization M₂ in the initial state may be parallel. In this case, the resistance value in the Z direction of the magnetic element 20 increases as the state of the magnetization M₁ changes (for example, as a change in angle from the initial state of the magnetization M₁ increases). When the initial state is a state in which the magnetization M₁ and the magnetization M₂ are parallel, it is preferable that the sensing current Is flow from the first ferromagnetic layer 1 to the second ferromagnetic layer 2. By allowing the sensing current Is to flow in this direction, a spin transfer torque which has the same direction as the magnetization M₂ of the second ferromagnetic layer 2 acts on the magnetization M₁ of the first ferromagnetic layer 1, and the magnetization M₁ and the magnetization M₂ in the initial state are parallel.

An example in which light applied to the magnetic element 20 has two levels of the first intensity and the second intensity has been described above, but the intensity of light applied to the magnetic element 20 may change at more levels or in an analog manner. In this case, the output voltage from the magnetic element 20 changes at the more levels or in an analog manner.

The optical device 100 according to the first embodiment can convert light to an electrical signal by converting light applied to the magnetic element 20 to an output voltage from the magnetic element 20. The optical device 100 according to the first embodiment is packaged, where the magnetic element 20 is disposed inside of the clad 12. Accordingly, the waveguide 10 in which light propagates and the magnetic element 20 for sensing light can be handled as a single component, and it is possible to decrease the size of the optical device 100. Since light propagating in the waveguide 10 is not externally output and is applied to the magnetic element 20, it is possible to decrease a loss of light due to reflection. By packaging the waveguide 10 and the magnetic element 20, adjustment in an optical axis of the waveguide 10 and the magnetic element 20 or the like is not necessary.

An example of the present invention has been described above in conjunction with the first embodiment, and the present invention is not limited to that embodiment.

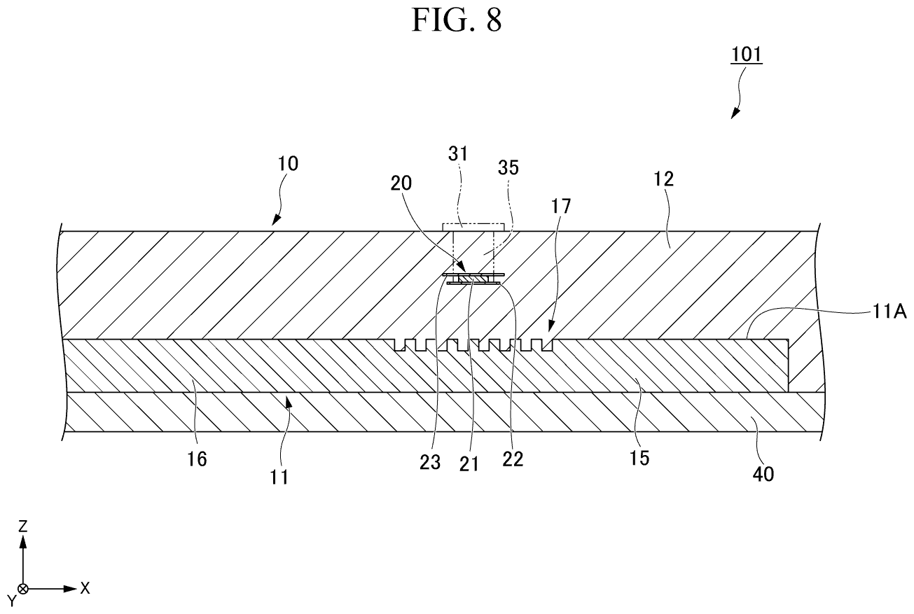

For example, FIG. 8 is a sectional view of an optical device 101 according to a first modified example. FIG. 8 illustrates an XZ section passing through the center in the Y direction of the core 11. The optical device 101 is different from the optical device 100 in that the magnetic element 20 is located above the waveguide 10 and the magnetic element 20 and the waveguide 10 are not in direct contact with each other. In the optical device 101, since light diffracted by the diffraction grating 17 is applied to the magnetic element 20, it is possible to convert light to an electrical signal. Since the optical device 101 according to the first modified example is packaged, it is possible to achieve the same effects as the optical device 100.

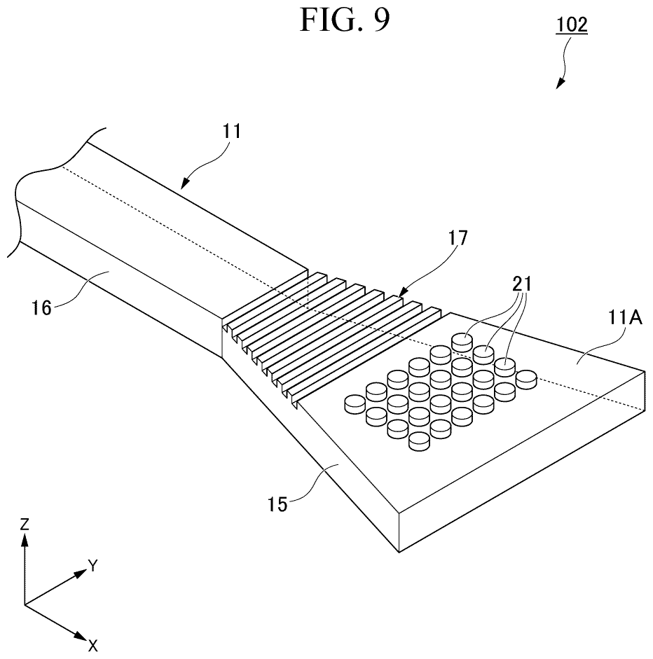

For example, FIG. 9 is a perspective view of an optical device 102 according to a second modified example. In FIG. 9, the terminal unit, the clad, and the substrate are not illustrated. The optical device 102 is different from the optical device 100 in that there are a plurality of magnetic elements 20 (laminates 21) and the magnetic elements 20 (laminates 21) do not overlap the diffraction grating 17 when seen in the Z direction.

The magnetic elements 20 (laminates 21) are located at positions not overlapping the diffraction grating 17 when seen in the Z direction of the element installation portion 15. Even when the magnetic elements 20 are located at positions deviated from the diffraction grating 17, light leakage diffracted by the diffraction grating 17 is applied to the magnetic elements 20, and thus it is possible to convert light to an electrical signal. The magnetic elements 20 formed on a flat surface have high crystallizability of the layers constituting the magnetic elements 20 and a large change in resistance (MR ratio).

When there are a plurality of magnetic elements 20, the optical device 102 can combine outputs from the magnetic elements 20 which adopt the same behavior in response to light. As a result, the optical device 102 can curb noise to an output signal. Accordingly, the optical device 102 has a high SN ratio.

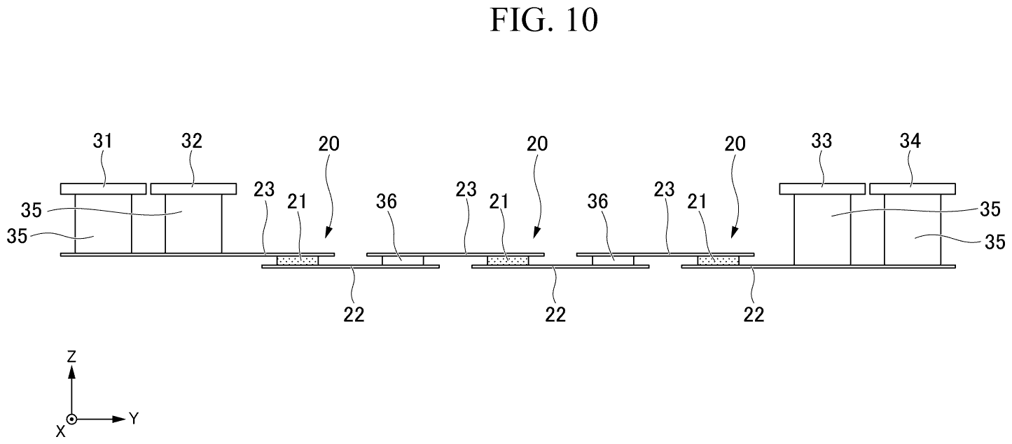

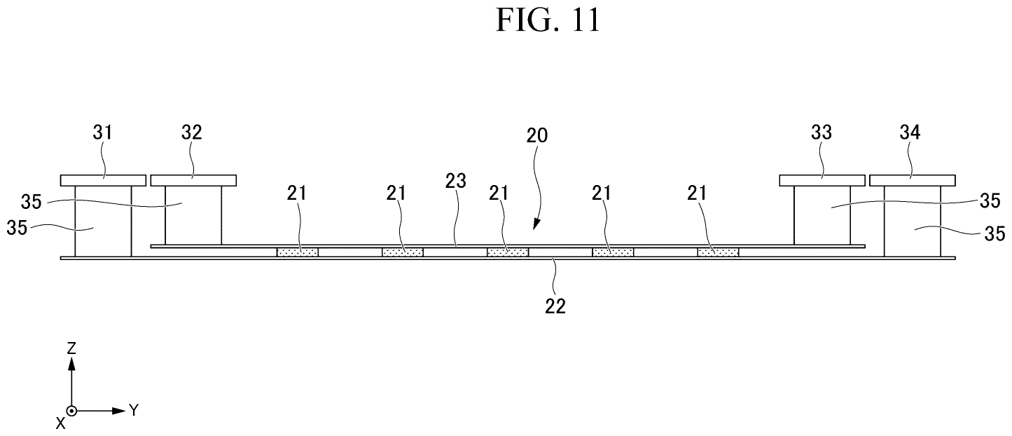

FIG. 10 is a sectional view illustrating a first example of a connection state of the magnetic elements in the optical device according to the second modified example. As illustrated in FIG. 10, the magnetic elements 20 may be connected in series. In FIG. 10, the magnetic elements 20 are connected in series by connection lines 36. FIG. 11 is a sectional view illustrating a second example of a connection state of the magnetic elements in the optical device according to the second modified example. As illustrated in FIG. 11, the magnetic elements 20 may be connected in parallel.

In the second modified example, there are a plurality of magnetic elements 20 (laminates 21), and the magnetic elements 20 (laminates 21) are located at positions not overlapping the diffraction grating 17 when seen in the Z direction, but only one of these differences may be employed. That is, the number of magnetic elements 20 may be one and the magnetic element 20 may be located at a position not overlapping the diffraction grating 17 when seen in the Z direction, or the number of magnetic elements 20 may be two or more and the magnetic elements may be located at positions overlapping the diffraction grating 17 when seen in the Z direction.

The optical devices according to the aforementioned embodiment and the modified examples can be used for various purposes.

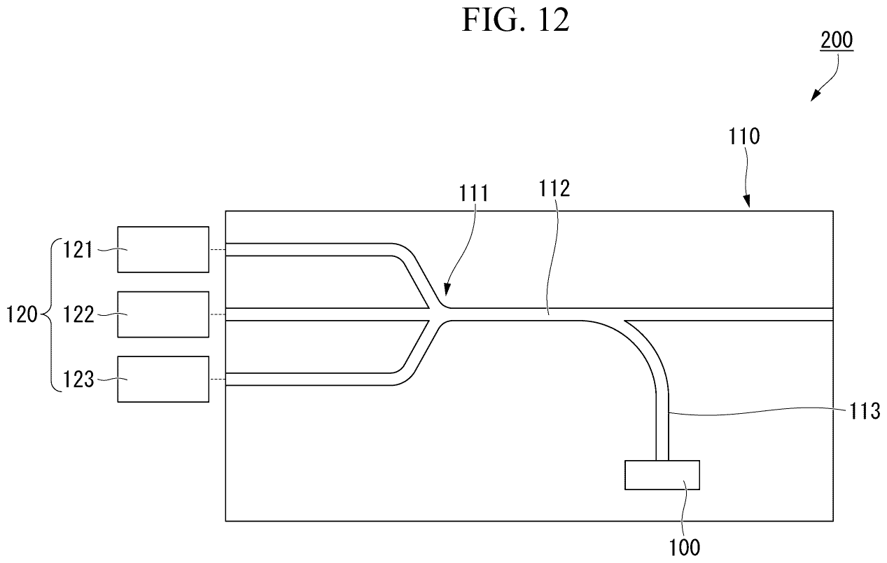

FIG. 12 is a diagram schematically illustrating an optical unit 200 according to a first application example. The optical unit 200 can be used, for example, as a part of an optical system. The optical unit 200 illustrated in FIG. 12 includes a waveguide unit 110 and a light source 120. The waveguide unit 110 includes the aforementioned optical device 100 and a waveguide 111. The waveguide 111 includes an output waveguide 112 and a monitoring waveguide 113. The output waveguide 112 is a waveguide for outputting light from the light source 120 to the outside. The monitoring waveguide 113 is a waveguide for divisionally outputting a part of light propagating in the output waveguide 112 to the optical device 100. The monitoring waveguide 113 is connected to the core 11 of the optical device 100.

The light source 120 is, for example, a laser light source. The light source 120 includes, for example, a red laser 121, a green laser 122, and a blue laser 123. Light output from the light source 120 propagates in the output waveguide 112 and is output to the outside. A part of light output from the light source 120 propagates in the monitoring waveguide 113 and reaches the optical device 100.

The optical unit 200 outputs laser light to the outside while monitoring the output from the light source 120 using the optical device 100. The optical unit 200 can adjust white balance of light output from the output waveguide 112 to the outside by adjusting the intensity of light output from the lasers.

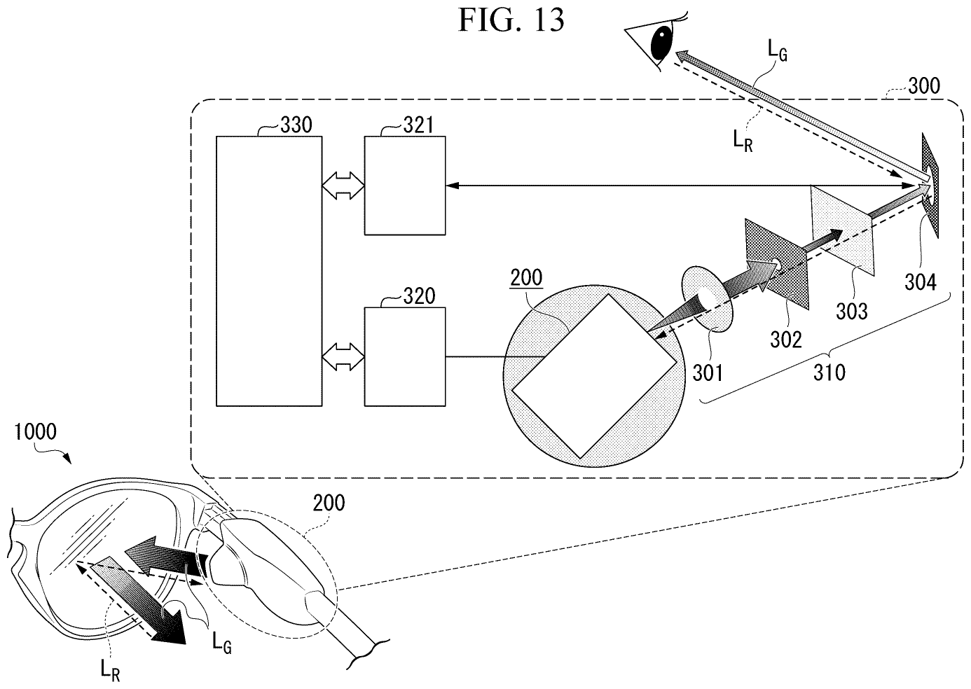

FIG. 13 is a conceptual diagram of an optical system 300 using the optical unit 200. The optical system 300 can be mounted, for example, in an eyeglass 1000.

The optical system 300 includes the optical unit 200, an optical system 310, drivers 320 and 321, and a controller 330. The optical system 310 includes, for example, a collimator lens 301, a slit 302, an ND filter 303, and an optical scanning mirror 304. The optical system 310 guides light output from the optical unit 200 to an irradiation subject (an eye in this example). The optical scanning mirror 304 is, for example, a two-axis MEMS mirror that changes a reflecting direction of laser light to a horizontal direction and a vertical direction. The optical system 310 is an example and is not limited to this example. The driver 320 controls the output from the light source 120 of the optical unit 200. The driver 321 is a control system for moving the optical scanning mirror 304. The controller 330 controls the drivers 320 and 321. Light L_{G} output from the light source 120 of the optical unit 200 propagates in the optical system 310, is reflected by a lens of the eyeglass 1000, and is incident on an eye. In this example, light is reflected by the lens of the eyeglass 1000, but light may be directly applied to the eye.

Light L_{G} of red, green, and blue emitted from the light source 120 displays an image. The image can be freely controlled. Output intensities of the red laser 121, the green laser 122, and the blue laser 123 can be adjusted on the basis of measurement results of an output from the optical device 100 which is irradiated with visible light output from the red laser 121, the green laser 122, and the blue laser 123.

By using this optical system 300, it is possible to project an image onto the eyeglass 1000. By monitoring the intensity of projected light using the optical device 100, it is possible to adjust color tones of an image.

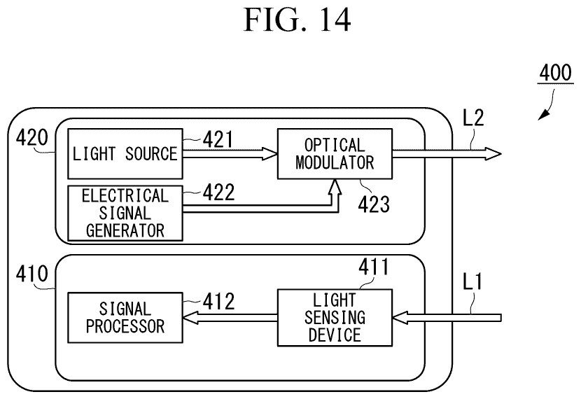

FIG. 14 is a block diagram illustrating a transceiver device 400 according to a second application example. The transceiver device 400 includes a receiver device 410 and a transmitter device 420. The receiver device 410 receives an optical signal L1, and the transmitter device 420 transmits an optical signal L2.

The receiver device 410 includes, for example, a light sensing device 411 and a signal processor 412. The aforementioned optical device can be used as the light sensing device 411. In the receiver device 410, for example, a light pulse is applied to an optical device of the light sensing device 411. The optical signal L1 includes a light pulse. The light sensing device 411 converts the optical signal L1 to an electrical signal. The signal processor 412 processes the electrical signal which is a conversion result from the light sensing device 411. The signal processor 412 receives a signal included in the optical signal L1 by processing the electrical signal from the light sensing device 411.

The receiver device 410 receives a signal included in the optical signal L1 on the basis of an output signal from the light sensing device 411.

The transmitter device 420 includes, for example, a light source 421, an electrical signal generator 422, and an optical modulator 423. The light source 421 is, for example, a laser unit. The light source 421 may be provided outside of the transmitter device 420. The electrical signal generator 422 generates an electrical signal on the basis of transmission information. The electrical signal generator 422 may form a unified body along with a signal converter in the signal processor 412. The optical modulator 423 modulates light output from the light source 421 on the basis of the electrical signal generated by the electrical signal generator 422 and outputs the optical signal L2.

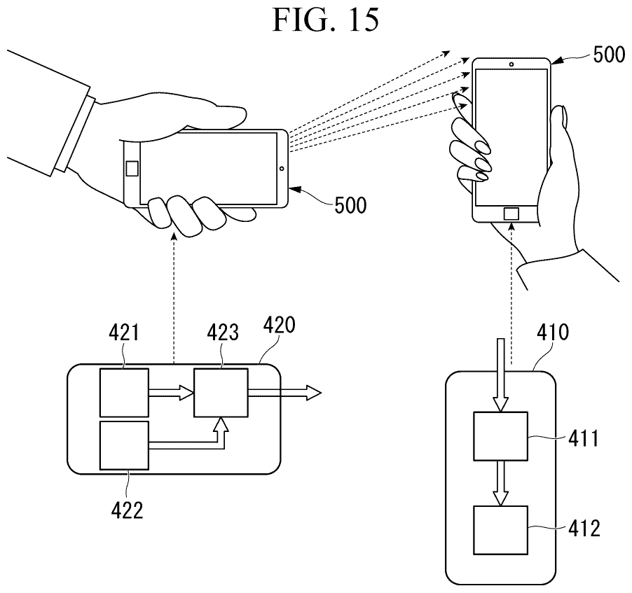

FIG. 15 is a conceptual diagram illustrating an example of a communication system. The communication system illustrated in FIG. 15 includes two terminal devices 500. The terminal devices 500 are, for example, smartphones, tablets, or personal computers.

Each terminal device 500 includes the receiver device 410 and the transmitter device 420. An optical signal transmitted from the transmitter device 420 of one terminal device 500 is received by the receiver device 410 of the other terminal device 500. Light used in transmission and reception between the terminal devices 500 is, for example, visible light. The receiver device 410 includes the light sensing device 411.

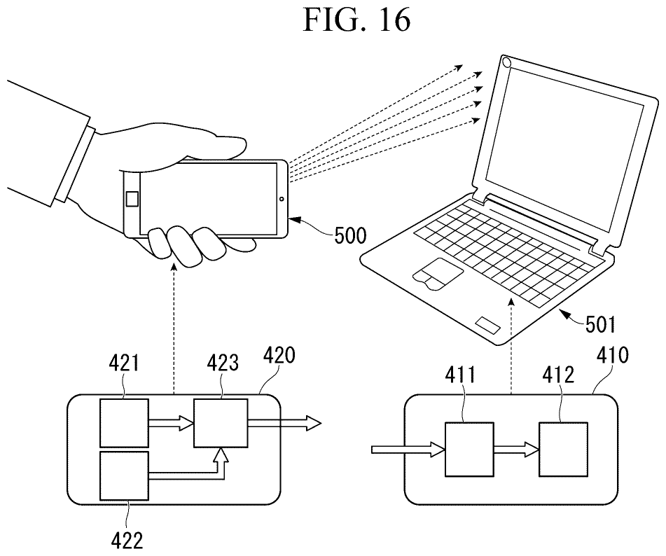

FIG. 16 is a conceptual diagram illustrating an example of a communication system. In the example illustrated in FIG. 15, both the terminal devices 500 are smartphones, but the terminal devices 500 may be different between a transmitting side and a receiving side. For example, a terminal device 500 illustrated in FIG. 16 is a smartphone, and a terminal device 501 is a personal computer.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

### EXPLANATION OF REFERENCES

1 First ferromagnetic layer
2 Second ferromagnetic layer
3 Spacer layer
4 Buffer layer
5 Seed layer
6 Third ferromagnetic layer
7 Magnetic coupling layer
8 Perpendicular magnetization inducing layer
9 Cap layer
10 Waveguide
11 Core
11A First surface
12 Clad
15 Element installation portion
16 Light propagating portion
17 Diffraction grating
17A Groove
17B Protrusion
20 Magnetic element
21 Laminate
22 First electrode
23 Second electrode
30 Terminal unit
31 First terminal
32 Second terminal
33 Third terminal
34 Fourth terminal
35 Via-line
36 Connection line
40 Substrate
100, 101, 102 Optical device

What is claimed is:

1. An optical device comprising:
a waveguide; and
at least one magnetic element,
wherein the waveguide includes a core in which light propagates and a clad which covers the core,
wherein the core includes a diffraction grating on a first surface, wherein the at least one magnetic element is located above the first surface in the clad, and
wherein the at least one magnetic element includes a first ferromagnetic layer, a second ferromagnetic layer, and a spacer layer which is located between the first ferromagnetic layer and the second ferromagnetic layer.

2. The optical device according to claim 1, wherein the at least one magnetic element is located at the same position as the diffraction grating or in front of the diffraction grating in a propagating direction of light which propagates in the core.

3. The optical device according to claim 1, wherein the at least one magnetic element is located at a position overlapping the diffraction grating when seen in a stacking direction.

4. The optical device according to claim 1, wherein the at least one magnetic element is located at a position not overlapping the diffraction grating when seen in a stacking direction.

5. The optical device according to claim 1, wherein the at least one magnetic element is in contact with the diffraction grating.

6. The optical device according to claim 1, wherein the core includes an element installation portion and a light propagating portion extending to the element installation portion, and
wherein a width of the core in the element installation portion is larger than a width of the core in the light propagating portion.

7. The optical device according to claim 1, wherein the at least one magnetic elements includes a plurality of magnetic elements.

8. A receiver device comprising the optical device according to claim 1.

9. A transceiver device comprising the receiver device according to claim 8.

10. A communication system comprising the receiver device according to claim 8.

11. A terminal device comprising the receiver device according to claim 8.

12. An optical system comprising the optical device according to claim 1.
